(19) United States
(12) Patent Application Publication
(10) Pub. No.: US 2024/0215158 A1
(43) Pub. Date: Jun. 27, 2024

(54) PRINTED CIRCUIT BOARD AND MANUFACTURING METHOD THEREOF

(71) Applicant: SAMSUNG ELECTRO-MECHANICS CO., LTD., Suwon-si (KR)

(72) Inventors: Mi Jeong JEON, Suwon-si (KR); Hyun Seok YANG, Suwon-si (KR); Tae Hee YOO, Suwon-si (KR); Chan Jin PARK, Suwon-si (KR)

(73) Assignee: SAMSUNG ELECTRO-MECHANICS CO., LTD., Suwon-si (KR)

(21) Appl. No.: 18/209,616

(22) Filed: Jun. 14, 2023

(30) Foreign Application Priority Data
Dec. 22, 2022 (KR) 10-2022-0181410

(51) Int. Cl. H05K 1/03; H05K 3/00; H05K 3/40

(52) U.S. Cl. CPC H05K 1/0306; H05K 3/0017; H05K 3/4038; H05K 2201/0338; H05K 2203/0186; H05K 2203/0315; H05K 2203/0582; H05K 2203/072; H05K 2203/0723

(57) ABSTRACT

A printed circuit board includes a first insulating layer, a first metal layer disposed on the first insulating layer and including a first oxidation region on a side surface thereof, and a second metal layer disposed on the first metal layer. A method of manufacturing a printed circuit board includes forming a first metal layer on a first insulating layer, forming a second metal layer on a portion of the first metal layer, oxidizing another portion of the first metal layer to form a first oxidation region, and removing at least a portion of the first oxidation region.

### CROSS-REFERENCE TO RELATED APPLICATION (S)

This application claims benefit of priority to Korean Patent Application No. 10-2022-0181410 filed on Dec. 22, 2022 in the Korean Intellectual Property Office, the disclosure of which is incorporated herein by reference in its entirety.

### TECHNICAL FIELD

The present disclosure relates to a printed circuit board and a manufacturing method thereof.

### BACKGROUND

In order to cope with the recent trend for lightweight, miniaturized mobile devices, there has been an increasing need to realize lightweight, thin and small printed circuit boards mounted therein. Meanwhile, as mobile devices have become light, thin and compact, an undercut phenomenon occurs during the process of implementing microcircuits, which may cause defects in microcircuits. In response to technical demand therefor, research has been conducted to improve reliability, while realizing circuits with fine line widths and intervals.

### SUMMARY

Exemplary embodiments provide a printed circuit board capable of implementing a fine metal layer and a method of manufacturing the printed circuit board.

Exemplary embodiments provide a printed circuit board in which a fine metal layer may be applied to various components, and a method of manufacturing the printed circuit board.

Exemplary embodiments provide a printed circuit board and a printed circuit board and manufacturing method capable of improving reliability.

According to an aspect of the present disclosure, a printed circuit board includes: a first insulating layer; a first metal layer disposed on the first insulating layer and including a first oxidation region on a side surface thereof; and a second metal layer disposed on the first metal layer.

According to another aspect of the present disclosure, a method of manufacturing a printed circuit board includes: forming a first metal layer on a first insulating layer; forming a second metal layer on a portion of the first metal layer; oxidizing another portion of the first metal layer to form a first oxidation region; and removing at least a portion of the first oxidation region.

According to another aspect of the present disclosure, a printed circuit board includes: a first insulating layer; a first metal layer; a second metal layer having a thickness greater than the first metal layer and disposed on the first metal layer; and a second insulating layer disposed on the first insulating layer to cover side surfaces of the first metal layer and the second metal layer. The first metal layer includes an end portion having a composition different from a center portion and being in contact with the second insulating layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating a printed circuit board according to an example;

FIG. 4 is a cross-sectional view schematically illustrating a printed circuit board according to another example;

FIG. 5 is a cross-sectional view schematically illustrating a printed circuit board according to another example;

FIG. 6 is a cross-sectional view schematically illustrating a printed circuit board according to another example;

FIG. 7 is a cross-sectional view schematically illustrating a printed circuit board according to another example;

FIGS. 8 and 9 are cross-sectional views schematically illustrating a method of manufacturing a printed circuit board according to an example; and

FIGS. 10 and 11 are cross-sectional views schematically illustrating a method of manufacturing a printed circuit board according to another example.

### DETAILED DESCRIPTION

Hereinafter, the present disclosure will be described with reference to the accompanying drawings. The shapes and sizes of elements in the drawings may be exaggerated or reduced for clearer description.

### Electronics

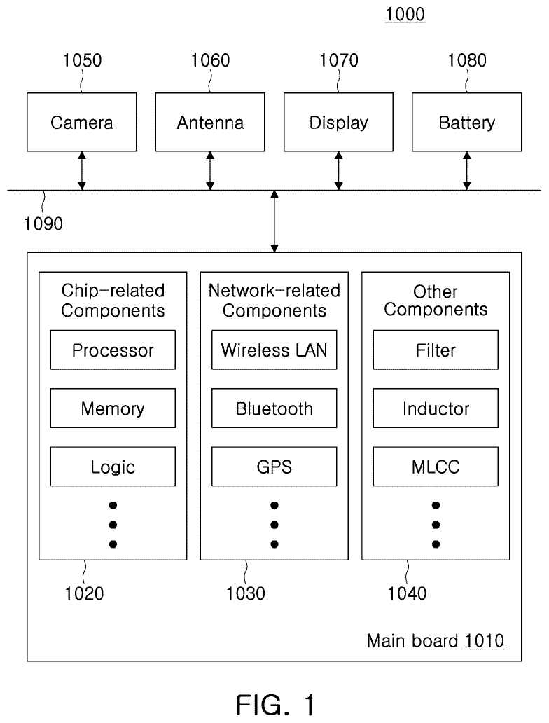

FIG. 1 is a block diagram schematically illustrating an example of an electronic device system.

Referring to FIG. 1, an electronic device 1000 accommodates a main board 1010. A chip-related component 1020, a network-related component 1030, and other components 1040 are physically and/or electrically connected to the main board 1010. These components are combined with other electronic components to be described below to form various signal lines 1090.

The chip-related component 1020 includes memory chips, such as volatile memories (e.g., DRAM), non-volatile memory (e.g., ROM), and flash memories; application processor chips, such as central processors (e.g., CPUs), graphics processors (e.g., GPUs), digital signal processors, encryption processors, microprocessors, and microcontrollers; logic chips, such as analog-to-digital converters (ADCs), and application-specific integrated circuits (ASICs), but is not limited thereto and may include other types of chip-related electronic components as well. In addition, these chip-related components 1020 may be combined with each other. The chip-related component 1020 may be in the form of a package including the aforementioned chip or electronic component.

The network related component 1030 may include Wi-Fi (IEEE 802.11 family, etc.), WiMAX (IEEE 802.16 family, etc.), IEEE 802.20, long term evolution (LTE), Ev-DO, HSPA+, HSDPA+, HSUPA+, EDGE, GSM, GPS, GPRS, CDMA, TDMA, DECT, Bluetooth, 3G, 4G, 5G, and any other wireless and wired protocols designated thereafter, but is not limited to and may include any of other wireless or wired standards or protocols. In addition, the network-related component 1030 and the chip-related component 1020 may be combined with each other.

The other components 1040 include high-frequency inductors, ferrite inductors, power inductors, ferrite beads, low temperature co-firing ceramics (LTCCs), electro-magnetic interference (EMI) filters, multi-layer ceramic condensers (MLCCs), and the like. However, the other components 1040 are not limited thereto and may include passive elements in the form of chip components used for various other purposes. In addition, the other components 1040 may be combined with the chip-related component 1020 and/or the network-related component 1030.

Depending on the type of electronic device 1000, the electronic device 1000 may include other electronic components that may or may not be physically and/or electrically connected to the main board 1010. The other electronic components may include, for example, a camera 1050, an antenna 1060, a display 1070, and a battery 1080. However, the electronic components are not limited thereto and may include audio codecs, video codecs, power amplifiers, compasses, accelerometers, gyroscopes, speakers, mass storage devices (e.g., hard disk drives), compact disks (CDs), digital versatile disks (DVDs), etc. In addition, other electronic components used for various purposes may be included depending on the type of the electronic device 1000.

The electronic device 1000 may include smartphones, personal digital assistants (PDAs), digital video cameras, digital still cameras, network systems, computers, monitors, tablets, laptops, netbooks, televisions, video game machines, smart watches, automotives, and the like. However, the electronic device 1000 is not limited thereto, and may be any other electronic device that processes data in addition thereto.

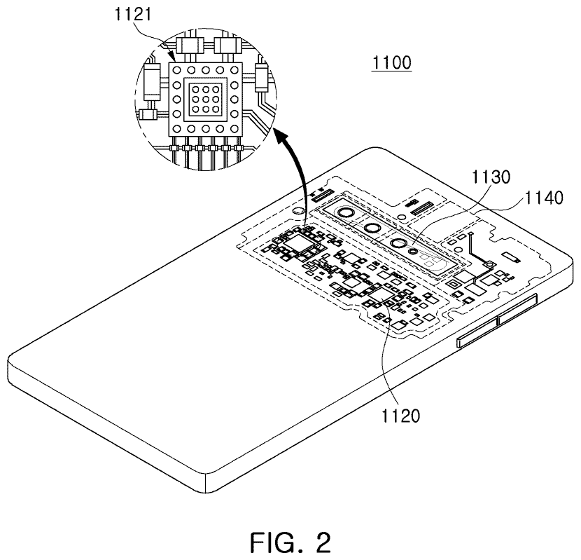

FIG. 2 is a perspective view schematically illustrating an example of an electronic device.

Referring to FIG. 2, the electronic device may be, for example, a smartphone 1100. A motherboard 1110 is accommodated the smartphone 1100, and various components 1120 are physically and/or electrically connected to the motherboard 1110. In addition, other components that may or may not be physically and/or electrically connected to the motherboard 1110, such as a camera module 1130 and/or a speaker 1140, are accommodated in the smartphone 1100. Some of the components 1120 may be the aforementioned chip-related components, for example, a component package 1121, but is not limited thereto. The component package 1121 may be in the form of a printed circuit board on which electronic components including active components and/or passive components are surface-mounted. Alternatively, the component package 1121 may be in the form of a printed circuit board in which active components and/or passive components are embedded. Meanwhile, the electronic device is not necessarily limited to the smartphone 1100, and may be other electronic devices as described above.

### Printed Circuit Board

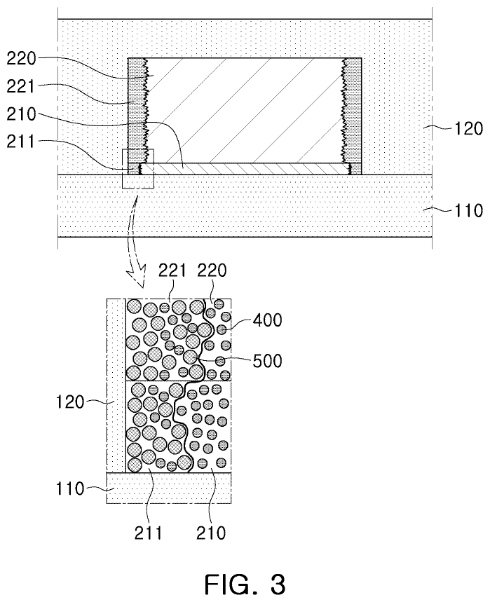

FIG. 3 is a cross-sectional view schematically illustrating a printed circuit board according to an example.

Referring to FIG. 3, a printed circuit board according to an example includes a first insulating layer 110, a first metal layer 210 disposed on the first insulating layer 110, and a second metal layer 220 disposed on the first metal layer 210. The first metal layer 210 may include a first oxidation region 211 on a side surface thereof, and the second metal layer 220 may include a second oxidation region 221 on a side surface thereof.

The first insulating layer 110 may include an insulating material. The insulating material may include thermosetting resins, such as epoxy resins, thermoplastic resins, such as polyimide, or materials including inorganic fillers, organic fillers, and/or glass fibers (glass cloth, and/or glass fabric) together with these resins. The insulating material may be a photosensitive material and/or a non-photosensitive material. For example, the insulating material may include solder resist (SR), Ajinomoto build-up film (ABF), FR-4, bismaleimide triazine (BT), prepreg (PPG), resin coated copper (RCC) insulating materials, copper clad laminate (CCL), but is not limited thereto, and other polymer materials may be used.

The first metal layer 210 may be disposed on the first insulating layer 110. The first metal layer 210 may be disposed on an upper surface of the first insulating layer 110 and may have a structure protruding from the first insulating layer 110, but is not limited thereto, and may be partially buried in the first insulating layer 110.

The first metal layer 210 includes metal particles 400. The metal particle 400 may be copper (Cu), aluminum (Al), silver (Ag), tin (Sn), gold (Au), nickel (Ni), lead (Pb), titanium (Ti), and/or alloys thereof. The first metal layer 210 may have a shape in which metal particles 400 are arranged. In FIG. 3, the arrangement of the metal particles 400 is shown to be free, but the present disclosure is not limited thereto and the metal particles 400 may have certain crystal grains and phases and densely arranged to constitute the first metal layer 210. In this case, some voids may exist between the metal particles 400 or between crystal grains and phases according to the arrangement of the metal particles 400, but these voids may be observed at an atomic arrangement level.

The first metal layer 210 may function as a seed layer. That is, the first metal layer 210 may function as a metal layer for the second metal layer 220 to be described below to be plated. Meanwhile, the first metal layer 210 is not limited thereto, and may provide a signal transmission path along with the second metal layer 220. The first metal layer 210 may be formed through electroless plating, and may be formed widely on the first insulating layer 110 and then partially removed to be patterned.

The second metal layer 220 may be disposed on the first metal layer 210. The second metal layer 220 includes metal particles 400. The metal particle 400 may be copper (Cu), aluminum (Al), silver (Ag), tin (Sn), gold (Au), nickel (Ni), lead (Pb), titanium (Ti), and/or alloys thereof. The metal particles 400 of the second metal layer 220 are preferably copper (Cu), but are not limited thereto. The second metal layer 220 may have a shape in which metal particles 400 are arranged. In FIG. 3, the arrangement of the metal particles 400 is free, but is not limited thereto. In this case, some voids may exist between the metal particles 400 or between crystal grains and phases according to the arrangement of the metal particles 400, but these voids may be observed at an atomic arrangement level.

The second metal layer 220 may be a general circuit pattern and may be formed in a plurality of patterns. The plurality of patterns may exchange electrical signals with different patterns and may also exchange electrical signals with metal layers further disposed on other layers. Meanwhile, the plurality of patterns may be electrically shorted with other patterns to perform a function or may allow a component to be mounted thereon. That is, the plurality of patterns may perform various functions according to the design.

The second metal layer 220 may be formed through electroplating using the first metal layer 210 as a seed layer. As a detailed method, the second metal layer 220 may be formed by any one of semi-additive process (SAP), modified semi-additive process (MSAP), tenting (TT), or subtractive method, but is not limited thereto, and among known methods for forming circuit patterns, electrolytic plating using a seed layer may be used without limitation.

Since the first metal layer 210 may function as a seed layer for plating the second metal layer 220 and the second metal layer 220 may function as a pattern, a thickness of the second metal layer 220 may be greater than that of the first metal layer 210. In this case, the thickness of the first metal layer 210 and the thickness of the second metal layer 220 may refer to a vertical distance between upper and lower surfaces thereof, respectively. That is, the thickness of the first metal layer 210 and the thickness of the second metal layer 220 may refer to the thickness of the printed circuit board in the stacking direction. In the present disclosure, the stacking direction of the printed circuit board may be understood as a direction in which the second metal layer 220 is stacked on the first metal layer 210, but is not limited thereto, and the stacking direction of the printed circuit board may refer to a direction in which the first metal layer 210 is stacked on the first insulating layer 110 or may refer to a direction in which the second insulating layer 120 to be described below is stacked on the first insulating layer 110. In FIG. 3, a vertical direction is shown as the stacking direction of the printed circuit board, but this is only an example and any direction may be used as long as the person skilled in the art may understand it without difficulty as a direction in which the components of the substrate are stacked.

The metal material of the first metal layer 210 and the metal material of the second metal layer 220 may be the same, but are not limited thereto, and may include different metal materials. For example, each of the first metal layer 210 and the second metal layer 220 may be metal layers respectively including copper (Cu), but are not necessarily limited thereto. As another example, the first metal layer 210 may include materials, such as aluminum (Al), silver (Ag), tin (Sn), gold (Au), nickel (Ni), lead (Pb), titanium (Ti), and/or alloys thereof, and the second metal layer 220 may also include copper (Cu). That is, the first metal layer 210 and the second metal layer 220 may include different metal materials. When the metal material of the first metal layer 210 and the metal material of the second metal layer 220 are different, the first metal layer 210 may be easily selectively removed in an operation of removing another portion of the first metal layer 210 during the manufacturing process. Since the first metal layer 210 is easily selectively removed, undercut may be prevented. In addition, when the first metal layer 210 is formed of titanium (Ti), since it has reactivity superior to that of copper (Cu) of the second metal layer 220, the degree of oxidation in the operation of oxidizing the first metal layer 210 may be faster. Meanwhile, when the first metal layer 210 is formed of nickel (Ni), an oxidation region denser than copper (Cu) of the second metal layer 220 may be formed. If there is a difference in the degree of oxidation between the first metal layer 210 and the second metal layer 220, it may be more advantageous to selectively remove the first oxidation region 211 of the first metal layer 210.

The first metal layer 210 and the second metal layer 220 may have a first oxidation region 211 and a second oxidation region 221, respectively. The first oxidation region 211 and the second oxidation region 221 may include metal oxide particles 500. The first oxidation region 211 and the second oxidation region 221 may be disposed on side surfaces of the first metal layer 210 and the second metal layer 220, respectively. The first oxidation region 211 and the second oxidation region 221 may be obtained by oxidizing the first metal layer 210 and the second metal layer 220, respectively. That is, the metal oxide particles 500 may be obtained by oxidizing metal particles 400 of the first metal layer 210 and the second metal layer 220, and as the metal oxide particles 500 are dispersed between the metal particles 400, the first oxidation region 211 and the second oxidation region 221 may be formed. At this time, since the first oxidation region 211 and the second oxidation region 221 are oxidized from the side surface of the first metal layer 210 and the side surface of the second metal layer 220, the distribution of the metal oxide particles 500 is the densest at the side surface of the first metal layer 210 and at the side surface of the second metal layer 220, and the distribution may be sparse toward a boundary of the first oxidation region 211 and a boundary of the second oxidation region 221. However, the present disclosure is not limited thereto and may have various distributions in a local area of the oxidation region.

The boundary of the first oxidation region 211 in the first metal layer 210 may not be formed as a smooth surface. The boundary of the first oxidation region 211 may refer to a boundary surface disposed in a direction opposite to the side surface of the first metal layer 210. That is, the boundary of the first oxidation region 211 may be understood as a boundary surface disposed toward the center of the first metal layer 210. Since the first oxidation region 211 may have a structure in which the metal oxide particles 500 penetrate between the metal particles 400, the boundary of the first oxidation region 211 may have a bumpy surface. The boundary surface of the first oxidation region 211 may be identified by observing a cross-section of the first metal layer 210 with a microscope. Meanwhile, without being limited thereto, a section in which a concentration having a predetermined ratio, compared to a concentration of the metal oxide particles 500, on the side surface of the first metal layer 210 may be understood as the boundary surface of the oxidation region 211. The boundary of the second oxidation region 221 may be interpreted by applying the same criteria as that of the boundary of the first oxidation region 211.

The thickness of the second oxidation region 221 may be greater than that of the first oxidation region 211. The thickness of the first oxidation region 211 and the thickness of the second oxidation region 221 may not mean the thickness in the stacking direction and may mean a distance between the side surface of the first metal layer 210 and the first oxidation region 211 and a distance between the side surface of the second metal layer 220 and the boundary of the second oxidation region 221. That is, the thickness of the first oxidation region 211 and the thickness of the second oxidation region 221 may each mean a thickness of the first oxidation region 211 and a thickness of the second oxidation region 221 in a direction, perpendicular to a direction in which the second metal layer 220 is stacked on the first metal layer 210. Since the first oxidation region 211 and the second oxidation region 221 may each have a non-uniform boundary surface, the thickness of the first oxidation region 211 and the thickness of the second oxidation region 221 at a cut surface of the printed circuit board may be measured by selecting a predetermined method. As an example, a certain range of the boundary of the first oxidation region 211 may be selected, a centerline of the boundary of the range may be calculated, and a distance from the corresponding centerline and the side surface of the first metal layer 210 may be calculated as the thickness. As another example, a certain range of the boundary of the first oxidation region 211 may be selected, and an average of thicknesses at five highest points of the boundary in the range and thicknesses at five lowest points may be calculated as the thickness. In either method, the accuracy of the thickness may be improved as the measurement is repeated by varying the measurement reference range. However, this is just one example of a method for measuring thickness, and any known method for measuring thickness may be used without limitation, and the thickness may be measured by using a known method for measuring roughness. However, the thickness of the second oxidation region 221 should be measured using the same reference and method as the method for measuring the thickness of the first oxidation region 211. The thickness of the second oxidation region 221 may be about several tens of nanometers (nm) to about several hundred nanometers (nm), for example, 50 nm to 500 nm, but is not necessarily limited thereto. That is, the thickness of the second oxidation region 221 may be 50 nm to 500 nm as the metal oxide particles 500 penetrate between the metal particles 400. Among them, the thickness of a portion forming the so-called oxide layer as the metal oxide particles 500 of the second oxidation region 221 are densely formed may be approximately 50 nm to 100 nm, but is not limited thereto. The thickness of the second oxidation region 221 may be formed to be several tens of nanometers (nm) thicker than the thickness of the first oxidation region 211, but is not necessarily limited to the numerical value, and the thickness of the second oxidation region 221 may be greater than the thickness of the first oxidation region 211. However, the aforementioned thickness range may be measured to be different depending on the measurement method.

The thickness of the first oxidation region 211 may be understood as a scale indicating the degree of oxidation of the first metal layer, and the thickness of the second oxidation region 221 may be understood as a scale indicating the degree of oxidation of the second metal layer. Therefore, the fact that the thickness of the second oxidation region 221 is greater than that of the first oxidation region 211 means that the degree of oxidation of the second metal layer is greater than the degree of oxidation of the first metal layer 210 under the same oxidation conditions. This is because, in the operation of oxidizing the metal layer during the manufacturing process of the printed circuit board, the side surface of the second metal layer 220 is exposed and directly oxidized, while only a partial region of the first metal layer 210 to be removed is exposed, direct oxidation is not performed and an oxidation region penetrated from the exposed surface remains. This will be described below in detail in the method of manufacturing a printed circuit board according to an example.

The printed circuit board according to an example may further include a second insulating layer 120 disposed on the first insulating layer 110. The second insulating layer 120 may include a material from the same insulating material group as that of the first insulating layer 110, and may include the same insulating material as that of the first insulating layer 110, but is not limited thereto.

The second insulating layer 120 may be disposed on the first insulating layer 110 to bury the first metal layer 210 and the second metal layer 220. The structure in which the first metal layer 210 and the second metal layer 220 are buried in the second insulating layer 120 may mean that the side surfaces of the first metal layer 210 and the second metal layer 220 and an upper surface of the second metal layer 220 are covered by the second insulating layer 120, and a lower surface of the first metal layer 210 is not covered by the second insulating layer 120 and is exposed to a lower surface of the second insulating layer 120.

In FIG. 3, the second insulating layer 120 is illustrated as being disposed on the first insulating layer 110, but is not limited thereto, and the upper and lower relationships in the drawing are only directions set for convenience. Considering the upside down printed circuit board of FIG. 3, the structure of the printed circuit board according to an example may be applied even in a so-called coreless structure manufactured using a carrier substrate.

Meanwhile, the printed circuit board according to an example may further include an insulating layer and a metal layer disposed on the lower surface of the first insulating layer 110 and the upper surface of the second insulating layer 120, and may further include a via for performing interlayer connection of the metal layer. In addition, without being limited thereto, the printed circuit board may further include general components of printed circuit boards, such as other insulating layers, other circuit patterns, through-vias, and cavities, which may be used by those skilled in the art.

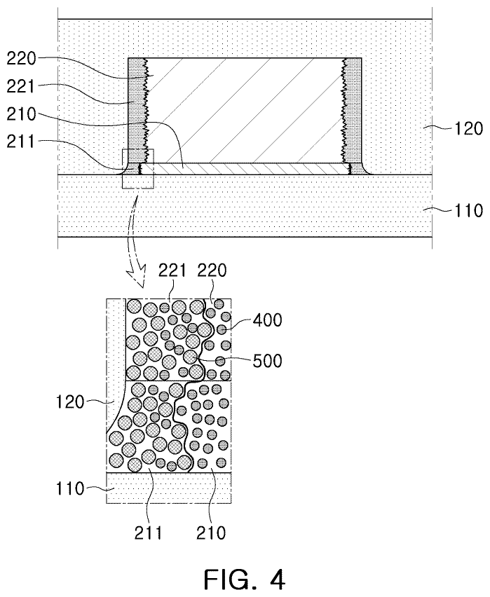

FIG. 4 is a cross-sectional view schematically illustrating a printed circuit board according to another example.

Referring to FIG. 4, the first oxidation region 211 of the first metal layer 210 protrudes relative to the side surface of the second metal layer 220. In the operation of removing the first oxidation region after oxidizing the first metal layer 210 in the manufacturing operation of the printed circuit board, the first oxidation region 211 of the first metal layer 210 may have a protruding structure. The fact that the first oxidation region 211 has a protruding structure means that the first oxidation region 211 may have a structure that protrudes, relative to the side surface of the second metal layer 220 and the removal of the first oxidation region 211 may not be complete. Since the first oxidation region 211 has low electrical conductivity or no conductivity, even if a portion of the first oxidation region 211 remains in the operation of removing the first oxidation region 211 during the manufacturing operation of the printed circuit board, a problem of electrical shorts may not occur. Therefore, even if the first oxidation region 211 is not completely removed along the side surface of the second oxidation region 221 of the second metal layer 220, the first metal layer 210 and the second metal layer 220 may smoothly perform a signal transmission function and the like.

Meanwhile, among components other than that the first oxidation region 211 of the first metal layer 210 protrudes relative to the side surface of the second metal layer 220, the same components as those of the printed circuit board according to an example may also be applied to a printed circuit board according to another example, and thus, redundant descriptions thereof will be omitted.

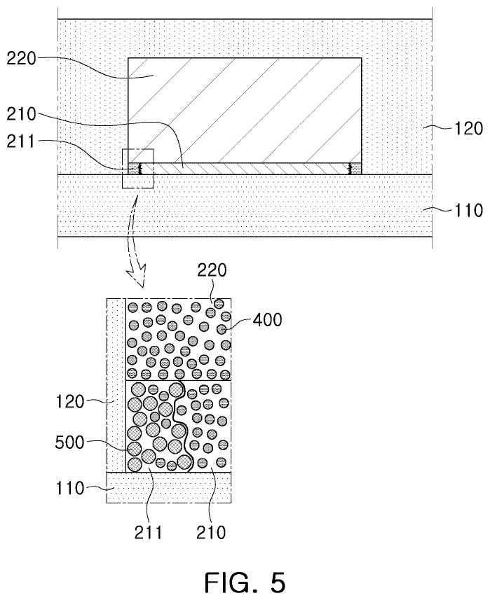

FIG. 5 is a cross-sectional view schematically illustrating a printed circuit board according to another example.

Referring to FIG. 5, in a printed circuit board according to another example, a portion of the side surface of the first metal layer 210 may include the first oxidation region 211, and the second metal layer 220 may not include the second oxidation region 221. In an operation of oxidizing a portion of the first metal layer 210 in the manufacturing operation of the printed circuit board according to another example, only the first metal layer 210 may be oxidized by controlling the second metal layer 220 not to be oxidized. Means for protection, such as a protective film or a mask, may be used on the upper and side surfaces of the second metal layer 220, and an anisotropic oxidation process may be used in the oxidation operation. As such, when only a portion of the first metal layer 210 is oxidized by preventing the second metal layer 220 from being oxidized, the second oxidation region 221 may not be formed and only the side surface of the first metal layer 210 is oxidized to form the first oxidation region 211.

Among the components other than the first oxidation region 211 and the second metal layer 220 of the first metal layer 210, the same components as those of the printed circuit board according to one example or the printed circuit board according to another example may also be applied to the printed circuit board according to still another example, and thus, a redundant description thereof will be omitted.

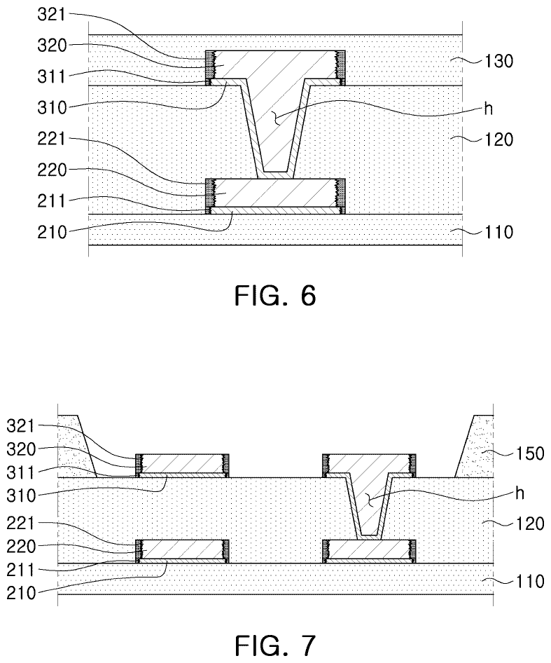

FIG. 6 is a cross-sectional view schematically illustrating a printed circuit board according to another example.

Referring to FIG. 6, the printed circuit board according to another example may further include a third insulating layer 130 disposed on the second insulating layer 120, a through-hole h penetrating through at least a portion of the second insulating layer 120, a third metal layer 310 disposed on an inner wall of the through-hole h, extending to at least a portion of the upper surface of the second insulating layer 120, and including a third oxidation region 311 on a side surface thereof, and a fourth metal layer 320 disposed on the third metal layer 310 to fill the through-hole h and including a fourth oxidation region 321 on a side surface thereof.

The through-hole h is disposed in the second insulating layer 120 and may pass through at least a portion of the second insulating layer 120. The through-hole h may correspond to a component for a via connecting a circuit layer disposed on the second insulating layer 120 and a circuit layer disposed on the first insulating layer 110.

The third metal layer 310 and the fourth metal layer 320 may be disposed in the through-hole h to function as vias for interlayer connection. The third metal layer 310 may function as a seed layer for the fourth metal layer 320 to be plated and may provide a signal transmission path together with the fourth metal layer 320. The third metal layer 310 may be formed through electroless plating, and the fourth metal layer 320 may be formed through electrolytic plating.

The third metal layer 310 may include the same metal material as that of the first metal layer 210, and the fourth metal layer 320 may include the same metal material as that of the second metal layer 220. That is, the third metal layer 310 and the fourth metal layer 320 may include the metal particles 400, and the metal particles 400 may include copper (Cu), aluminum (Al), silver (Ag), tin (Sn), gold (Au), nickel (Ni), lead (Pb), titanium (Ti), and/or alloys thereof. In addition, the third metal layer 310 and the fourth metal layer 320 may include the same metal material, but are not limited thereto, and the third metal layer 310 and the fourth metal layer 320 may include different metal materials. The third metal layer 310 and the fourth metal layer 320 may include a third oxidation region 311 and a fourth oxidation region 321 on side surfaces thereof, respectively. The third oxidation region 311 and the fourth oxidation region 321 may include metal oxide particles.

The third insulating layer 130 may include one material from a group of insulating materials, such as the first insulating layer 110, and may include the same insulating material as that of the first insulating layer 110 and/or the second insulating layer 120, but is not limited to.

The third metal layer 310 and the fourth metal layer 320 may correspond to the first metal layer 210 and the second metal layer 220, respectively, and the third oxidation region 311 and the fourth oxidation region 321 may correspond to the first oxidation region 211 and the second oxidation region 221, respectively. That is, the configuration of the printed circuit board according to an example is not limited to any one layer, and may be applied to a configuration for interlayer connection as in the printed circuit board according to another example.

Meanwhile, since the same components of the printed circuit board according to an example, the printed circuit board according to another example, and the printed circuit board according to still another example, among the components other than the third metal layer 310, the third oxidation region 311, the fourth metal layer 320, the fourth oxidation region 321, and the third insulating layer 130 may also be applied to the printed circuit board according to another example, a redundant description thereof will be omitted.

FIG. 7 is a cross-sectional view schematically illustrating a printed circuit board according to another example.

Referring to FIG. 7, the printed circuit board according to another example may further include a solder resist layer 150 disposed on the second insulating layer 120.

The solder resist layer 150 protects the printed circuit board from the outside. The solder resist layer 150 may include a thermosetting resin and an inorganic filler dispersed in the thermosetting resin, but may not include glass fibers. The insulating resin may be a photosensitive insulating resin, and the filler may be an inorganic filler and/or an organic filler, but is not limited thereto. However, the material of the solder resist layer 150 is not limited thereto, and other polymer materials may be used as needed, and the solder resist layer 150 may be configured as a known solder resist layer 150.

The solder resist layer 150 may include an opening, and the third metal layer 310 and the fourth metal layer 320 may be exposed to the outside through the opening. In FIG. 7, it is described that the upper surface of the second insulating layer 120 is exposed together by the opening of the solder resist layer 150, but is not limited thereto, and only the upper surface of the fourth metal layer 320 may be exposed by the opening of the solder resist layer 150 and the upper surface of the second insulating layer 120 and the side surfaces of the third metal layer 310 and the fourth metal layer 320 may be covered by the solder resist layer 150.

The fact that the solder resist layer 150 may be disposed on the second insulating layer 120 of another printed circuit board means that the third metal layer 310 and the fourth metal layer 320 of the printed circuit board according to another example function as a pad for mounting electronic components and the like. That is, it may mean that the third metal layer 310 and the fourth metal layer 320 may be disposed on the uppermost layer and at least a portion of the fourth metal layer 320 is exposed to the outside of the printed circuit board and may be connected to other components, such as electronic components.

Meanwhile, although not shown in FIG. 7, a surface treatment layer may be further provided on the fourth metal layer 320. The surface treatment layer may perform a function of improving bonding strength with connection means for connecting electronic components or improving reliability during signal transmission. The surface treatment layer may be used without limitation as long as it is a known means.

Meanwhile, among the components other than the solder resist layer 150, the same components as those of the printed circuit board according to one example the printed circuit board according to another example, and the printed circuit board according to still another example may also be applied to the printed circuit board according to yet another example, and thus, a redundant description thereof will be omitted.

### Method of Manufacturing Printed Circuit Board

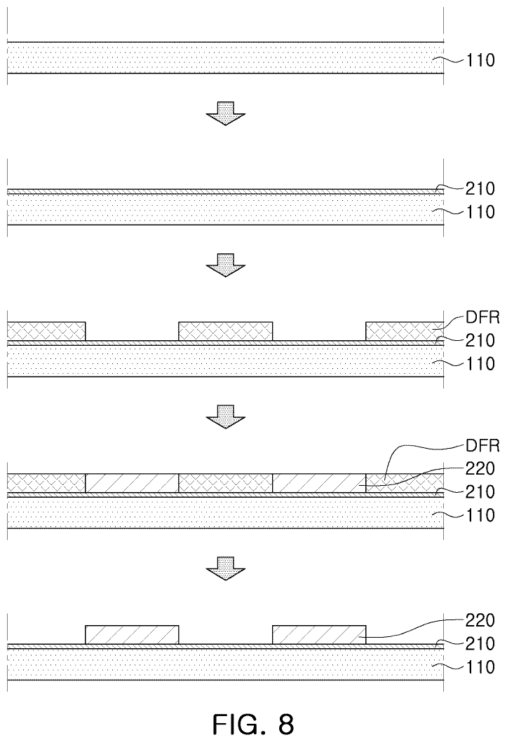

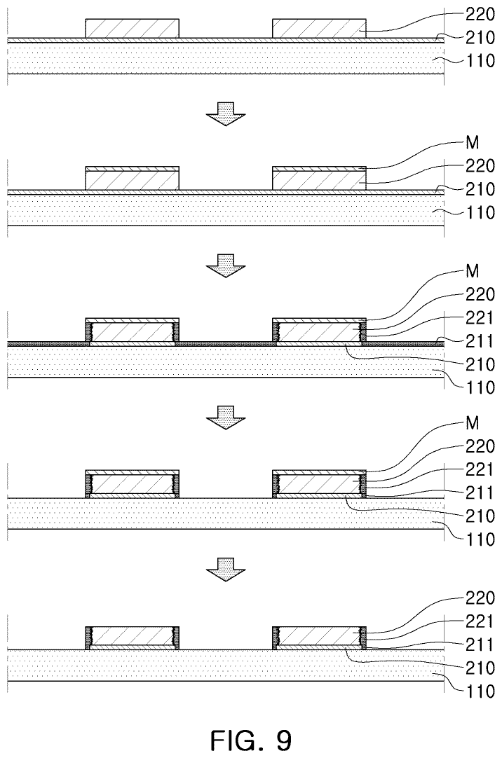

FIGS. 8 to 9 are cross-sectional views schematically illustrating a method of manufacturing a printed circuit board according to an example.

Referring to FIG. 8, a printed circuit board according to an example includes the first metal layer 210 formed on the first insulating layer 110. The first metal layer 210 may be formed through a known electroless plating method, but is not limited thereto, and it is also possible to prepare a material on which the first metal layer 210 is formed on the first insulating layer 110. The first metal layer 210 may function as a seed for plating the second metal layer 220 in an operation of forming the second metal layer 220, which will be described below.

Subsequently, a dry film resist DER is disposed on the first metal layer 210. As the dry film resist DER, a known dry film material may be used, but is not necessarily limited to the dry film resist DFR, and any material capable of functioning as a plating resist may be used without limitation. After disposing the dry film resist DFR on the first metal layer 210, the dry film resist DER may be patterned through exposure and development. In the operation of forming the second metal layer 220, which will be described below, the dry film resist DER may function as a plating resist, and the second metal layer 220 may be formed on the region of the first metal layer 210 in which the dry film resist DFR is not formed.

The second metal layer 220 is formed on the first metal layer 210. The second metal layer 220 may be formed through an electrolytic plating process using the first metal layer 210 as a seed layer. As described above, the second metal layer 220 may be formed in a region of the first metal layer 210 in which the dry film resist DFR is not formed.

Thereafter, the dry film resist DER is removed. A known method, such as delamination, may be used to remove the dry film resist DFR.

Referring to FIG. 9, a mask M is disposed on the second metal layer 220. The mask M corresponds to a means for protecting the second metal layer 220 from being oxidized in the operation of oxidizing the first metal layer 210. The mask M is temporarily disposed on the second metal layer 220, and an organic film or the like may be disposed. The mask M may not be necessarily attached on the second metal layer 220 and the mask M including an opening may be disposed to correspond to a region other than the region.

Subsequently, an operation of oxidizing the first metal layer 210 is performed. Since the first metal layer 210 serves as a seed layer, the first metal layer 210 other than the region in which the second metal layer 220 is patterned should be removed. In this case, the region of the first metal layer 210 to be removed may be pre-oxidized, thereby preventing an undercut in which the first metal layer 210 is removed during etching to remove the first metal layer 210.

The operation of oxidizing the first metal layer 210 may be performed by a method using heat, electrochemistry, chemical vapor, or plasma, but is not limited thereto, and any process of oxidizing a metal may be used without limitation. An exposed portion of the first metal layer 210 in which the second metal layer 220 is not formed may be exposed to an oxidizing condition, and the side surface of the second metal layer 220 may also be exposed to the oxidizing condition. Since the operation of directly oxidizing the first metal layer 210 is performed without attaching a metal oxide film on the first metal layer 210 and the second metal layer 220, the exposed portion of the first metal layer 210 is first oxidized, having a structure in which metal oxide particles are disposed between metal particles, and a concentration of the metal oxide particles may be higher in a portion exposed to the oxidizing condition in the first oxidation region. In the oxidation operation of the first metal layer 210, the metal oxide particles may penetrate into a partial region of the first metal layer 210 positioned below the second metal layer 220. Since the thickness of the first metal layer 210 is smaller than the thickness of the second metal layer 220, oxidation of the first metal layer 210 may proceed faster under the same oxidation condition, and the metal oxide particles may penetrate even to a lower portion of the second metal layer 220 which is not an exposed surface of the first metal layer 210.

An upper surface of the second metal layer 220 disposed on the mask M may not be oxidized. That is, a portion of the first metal layer 210 not covered by the mask M and a side surface of the second metal layer 220 may be oxidized, and the first oxidation region 211 and the second oxidation region 221 may be formed. That is, in the operation of oxidizing the first metal layer 210, a portion of the second metal layer 220 may be oxidized together.

Since the first oxidation region 211 of the first metal layer 210 penetrates into the lower portion of the second metal layer 220, while the side surface of the second metal layer 220 is directly exposed to the oxidation condition, in the printed circuit board according to an example, the thickness of the second oxidation region 221 may be greater than that of the first oxidation region 211. The thickness of the second oxidation region 221 may be larger than the thickness of the first oxidation region 211 by several tens of nanometers, but is not necessarily limited thereto. Meanwhile, in a case in which oxidation of the second metal layer 220 is minimized by adjusting the oxidation condition differently, the thickness of the second oxidation region 221 may be smaller than or the same as that of the first oxidation region 211.

Thereafter, at least a portion of the first oxidation region 211 in the first metal layer 210 may be removed. The operation of removing a portion of the first oxidation region 211 may be performed by performing a process, such as etching, or a dry etching process may be performed. Since etching rates of the metal layer and the oxidation region are different, the portion corresponding to the first oxidation region 211 may be removed, even through a dry etching process. However, the present disclosure is not limited thereto, and a process of removing a metal layer or a process of removing an oxide layer may be used, and any known process of removing a seed layer may be used without limitation. In particular, even if a wet etching process is performed, the degree to which the oxidation region is removed is different from the degree to which the metal layer is removed, and thus, the wet etching process may be easier in selective removal.

That is, the operation of removing at least a portion of the first oxidation region 211 in the present disclosure is to remove only the oxidation region through selective etching of the seed layer. Since the known seed layer removal removes only an unnecessary portion from the metal layer, it may be difficult to precisely remove the unnecessary portion. Meanwhile, since the region to be removed from the seed layer is oxidized as a target and then the oxidation region is removed, an undercut phenomenon that may occur in the known seed layer may be prevented. That is, since only a portion of the first oxidation region 211 of the first metal layer 210 may be removed, other regions of the first metal layer 210 are not etched and the undercut phenomenon may be prevented.

In this case, the mask M disposed in the previous operation may be used in the etching step, but a new mask may be used without being limited thereto. The upper surface of the second metal layer 220 may be protected by the mask M, and a width of the second metal layer 220 and a width of the first metal layer 210 may be determined according to a size of the mask M. Even in the operation of removing at least a portion of the first oxidation region 211, since the second metal layer 220 covered by the mask M is not etched, the second oxidation region 221 formed on the second metal layer 220 may remain and the first oxidation region 211 penetrating into the lower portion of the second metal layer 220 may also remain without being removed. In the operation of removing at least a portion of the first oxidation region 211 from the first metal layer 210, when a portion of the first oxidation region 211 is not completely removed according to an etching degree, a portion of the first oxidation region 211 may protrude, relative to the side surface of the second metal layer 220 as shown in FIG. 4.

Thereafter, an operation of removing the mask M may be performed to complete the first metal layer 210 and the second metal layer 220. A method of removing the mask M may be appropriately selected according to the type of the mask M.

Thereafter, the second insulating layer 120 may be further formed on the first insulating layer 110, and a metal layer and an oxidation region may be disposed on other layers as well. Of course, the shapes of the first metal layer 210 and the second metal layer 220 may vary. It is not limited to those shown in FIGS. 8 to 9, and after forming a through-hole penetrating through the insulating layer as in the printed circuit board according to another example shown in FIG. 6 or 7, the metal layer and the oxidation region may be disposed or a solder resist layer may be further formed on the insulating layer in the same manner.

In addition, the general components of the printed circuit board may be further included as described above in the description of the printed circuit board according to an example, and may be freely added or omitted without changing the technical meaning of the present disclosure.

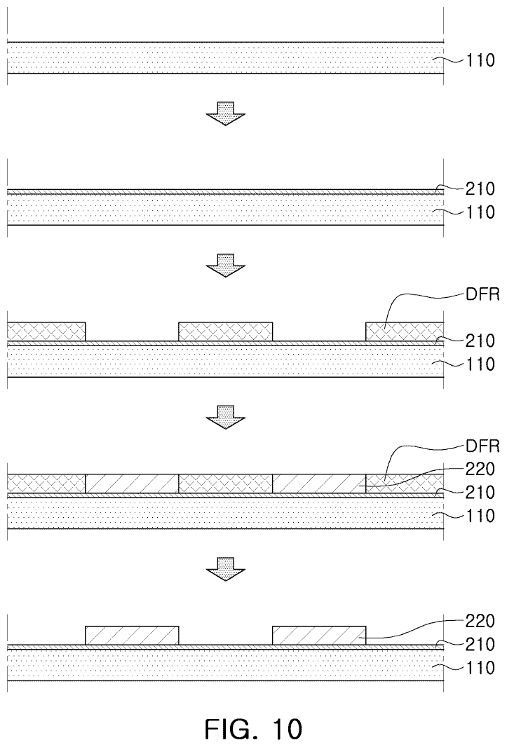

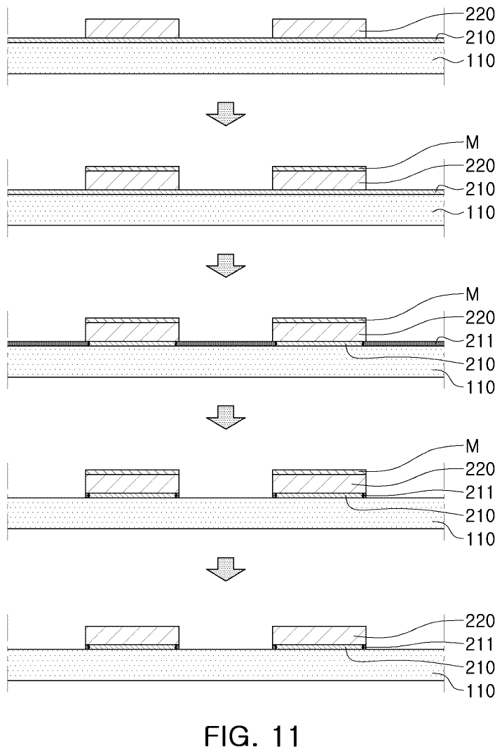

FIGS. 10 to 11 are cross-sectional views schematically illustrating a method of manufacturing a printed circuit board according to another example.

Referring to FIG. 10, the operation of disposing the first metal layer 210 and patterning the second metal layer 220 may be performed in the same operation as that of the method of manufacturing the printed circuit board according to an example.

Referring to FIG. 11, in the operation of oxidizing the first metal layer 210, the second metal layer 220 may not be oxidized. In the operation of oxidizing the first metal layer 210, an oxidation process may be selected to have a certain directivity or the metal materials of the first metal layer 210 and the second metal layer 220 may be different so that the second metal layer 220 may not be oxidized. Meanwhile, without being limited thereto, a method of selectively oxidizing only the first metal layer 210, without oxidizing the second metal layer 220, may be used, such as using a mask covering all the exposed surfaces of the second metal layer 220 before the oxidation operation.

Among other operations, the same components as those of the method of manufacturing a printed circuit board according to an example or the method of manufacturing a printed circuit board according to another example may also be applied to a printed circuit board according to another example, and therefore, redundant descriptions thereof will be omitted.

In the present disclosure, the meaning of cross-section may mean a cross-sectional shape when an object is vertically cut, or a cross-sectional shape when the object is viewed from a side-view. In addition, the meaning on a plane may be a shape when the object is horizontally cut or a planar shape when the object is viewed from a top-view or bottom-view.

As one of the various effects of the present disclosure, it is possible to provide a printed circuit board capable of implementing a fine metal layer, and a method of manufacturing the printed circuit board.

As another effect among several effects of the present disclosure, it is possible to provide a printed circuit board in which a fine metal layer may be applied to various components, and a method of manufacturing the printed circuit board.

As another one of the various effects of the present disclosure, it is possible to provide a printed circuit board and a method of manufacturing the printed circuit board capable of improving reliability.

While example exemplary embodiments have been shown and described above, it will be apparent to those skilled in the art that modifications and variations could be made without departing from the scope of the present disclosure as defined by the appended claims.

What is claimed is:

1. A printed circuit board comprising:
a first insulating layer;
a first metal layer disposed on the first insulating layer and including a first oxidation region on a side surface thereof; and
a second metal layer disposed on the first metal layer.

2. The printed circuit board of claim 1, wherein
the first metal layer includes metal particles,
the first oxidation region includes metal particles and metal oxide particles, and
the metal oxide particles are disposed between the metal particles in the first oxidation region.

3. The printed circuit board of claim 1, wherein the second metal layer includes a second oxidation region on a side surface thereof.

4. The printed circuit board of claim 3, wherein
the first metal layer and the second metal layer include metal particles,
the first oxidation region and the second oxidation region include metal particles and metal oxide particles, and
the metal oxide particles are disposed between the metal particles in each of the first oxidation region and the second oxidation region.

5. The printed circuit board of claim 4, wherein a thickness of the second oxidation region in a direction, perpendicular to a stacking direction of the first metal layer and the second metal layer is greater than a thickness of the first oxidation region in the direction, perpendicular to the stacking direction of the first metal layer and the second metal layer.

6. The printed circuit board of claim 1, wherein a thickness of the second metal layer in a stacking direction of the first metal layer and the second metal layer is greater than a thickness of the first metal layer in the stacking direction of the first metal layer and the second metal layer.

7. The printed circuit board of claim 1, wherein the first oxidation region protrudes relative to a side surface of the second metal layer.

8. The printed circuit board of claim 1, wherein the first metal layer includes a metal, different from the second metal layer.

9. The printed circuit board of claim 1, further comprising:
a second insulating layer disposed on the first insulating layer;
a through-hole penetrating through at least a portion of the second insulating layer;
a third metal layer disposed on an inner wall of the through-hole, extending to at least a portion of an upper surface of the second insulating layer, and including a third oxidation region on a side surface thereof; and
a fourth metal layer disposed on the third metal layer to fill the through-hole.

10. The printed circuit board of claim 9, wherein the fourth metal layer includes a fourth oxidation region on a side surface thereof.

11. The printed circuit board of claim 9, further comprising a solder resist layer disposed on the second insulating layer.

12. A method of manufacturing a printed circuit board, the method comprising:
forming a first metal layer on a first insulating layer;
forming a second metal layer on a portion of the first metal layer;
oxidizing another portion of the first metal layer to form a first oxidation region; and
removing at least a portion of the first oxidation region.

13. The method of claim 12, wherein in the forming of the first oxidation region, the first oxidation region is further formed on a portion of the first metal layer disposed on a lower surface of the second metal layer.

14. The method of claim 12, further comprising disposing a mask on the second metal layer, before forming the first oxidation region.

15. The method of claim 14, wherein the forming of the first oxidation region includes oxidizing a portion of a side surface of the second metal layer together to form a second oxidation region.

16. The method of claim 12, wherein the removing of at least a portion of the first oxidation region is performed by a dry etching method.

17. The method of claim 12, wherein the forming of the first metal layer is performed by electroless plating, and the forming of the second metal layer is performed by electroplating.

18. A printed circuit board comprising:
a first insulating layer;
a first metal layer;
a second metal layer having a thickness greater than the first metal layer and disposed on the first metal layer; and
a second insulating layer disposed on the first insulating layer to cover side surfaces of the first metal layer and the second metal layer,
wherein the first metal layer includes an end portion having a composition different from a center portion and being in contact with the second insulating layer.

19. The printed circuit board of claim 18, wherein the second metal layer includes an end portion having a composition different from a center portion of the second metal layer and being in contact with the second insulating layer.

20. The printed circuit board of claim 18, wherein the end portion of the first metal layer protrudes relative to the side surface of the second metal layer.

21. The printed circuit board of claim 18, wherein the first metal layer includes a metal different from the second metal layer.

22. The printed circuit board of claim 18, wherein the end portion of the first metal layer at least partially overlaps with the second metal layer in a stacking direction of the first metal layer and the second metal layer.

23. The printed circuit board of claim 18, wherein a width, in a direction perpendicular to a stacking direction of the first metal layer and the second metal layer, of the first metal layer increases in a direction from the second metal layer to the first insulating layer.
